(19) United States
(12) Patent Application Publication
(10) Pub. No.: US 2017/0141077 A1
(43) Pub. Date: May 18, 2017

(54) ORGANIC ELECTROLUMINESCENT DEVICE, MANUFACTURING METHOD THEREOF AND DISPLAY DEVICE

(71) Applicants: Boe Technology Group Co., Ltd., Beijing (CN); Ordos Yuansheng Optoelectronics Co., Ltd., Inner Mongolia (CN)

(72) Inventors: Xiaojin Zhang, Beijing (CN); Lei Chen, Beijing (CN); Dini Xie, Beijing (CN)

(21) Appl. No.: 15/322,555

(22) PCT Filed: Apr. 20, 2016
(86) PCT No.: PCT/CN2016/079735

§ 371 Date: Dec. 28, 2016

(30) Foreign Application Priority Data
Jun. 4, 2015 (CN) 201510303036.1

(51) Int. Cl. H01L 25/04; H01L 51/56; H01L 27/32; H01L 51/00; H01L 51/52

(52) U.S. Cl. CPC H01L 25/048; H01L 51/0096; H01L 51/5281; H01L 27/3209; H01L 51/5275; H01L 27/3237; H01L 51/56; H01L 2251/5315

(57) ABSTRACT

The embodiments of the present invention provide an organic electroluminescent device, manufacturing method thereof and display device, which relate to the field of display technology. The organic electroluminescent device comprises: a basal substrate with phase retardation characteristic; a polarization structure provided on a side of the basal substrate; a first organic electroluminescent unit located on a side of the polarization structure departing from the basal substrate; a side of the first organic electroluminescent unit departing from the basal substrate being the light exit side of the organic electroluminescent device; and at least a second organic electroluminescent unit located on a side of the basal substrate departing from the first organic electroluminescent unit. The light color of the organic electroluminescent device is adjustable; the color purity of the emitted light is relatively high. In addition, the contrast of the organic electroluminescent device is also high.

### TECHNICAL FIELD

The present invention relates to the field of display technology, in particular to an organic electroluminescent device, manufacturing method thereof and display device.

### BACKGROUND

In the existing organic electroluminescent devices, the design of stacked organic electroluminescent units (stacked OLED) can be applied to realize the function of adjustable light color. In the structure of the stacked OLED, several single OLED units are stacked perpendicularly on the substrate surface; each OLED unit is driven with a single power source. By controlling the light emitting state of each OLED unit respectively, the OLED device can emit light of different colors, achieving the function of adjustable light color. However, in the existing stacked OLED devices, before a light beam emitted by a certain OLED unit is emitted from the light exit surface of the OLED device, the light beam may pass through other OLED units stacked with the certain OLED unit; while the light beam passes through other OLED units, if the photon energy of the light beam is large, the light beam may excite luminescence in the light emitting layers of other OLED units, resulting in impure light color of the OLED device.

### SUMMARY

The embodiments of the present invention provide an organic electroluminescent device, manufacturing method thereof and display device. The light color of the organic electroluminescent device is adjustable; the color purity of the emitted light is relatively high.

To this end, the embodiments of the present invention provide the following solutions.

An embodiment of the present invention provides an organic electroluminescent device. The organic electroluminescent device comprises: a basal substrate with phase retardation characteristic; a polarization structure provided on a side of the basal substrate; a first organic electroluminescent unit located on a side of the polarization structure departing from the basal substrate; a side of the first organic electroluminescent unit departing from the basal substrate being the light exit side of the organic electroluminescent device; and at least a second organic electroluminescent unit located on a side of the basal substrate departing from the first organic electroluminescent unit.

In the organic electroluminescent device, by respectively adjusting the light emitting state of the first organic electroluminescent unit and the second organic electroluminescent unit, light of different colors can be emitted, realizing the function of adjustable light color.

In addition, in the organic electroluminescent device, the polarization structure and the basal substrate are arranged on a side of the first organic electroluminescent unit departing from the light exit side. Therefore, when the first organic electroluminescent unit emits light, most of the generated light can be emitted from the light exit side; only a small part of the light can pass through the polarization structure and the basal substrate, and enter the light emitting layer of the second organic electroluminescent unit. Even if a part of light emitted by the first organic electroluminescent unit passes through the polarization structure and the basal substrate, and enters the second organic electroluminescent unit, this part of light cannot pass through the polarization structure again or exit from the light emitting side due to the isolation function of the basal substrate with phase retardation characteristic and the polarization structure.

Optionally, a wavelength emitted by the first organic electroluminescent unit is smaller than a wavelength emitted by the second organic electroluminescent unit.

Optionally, the first organic electroluminescent unit is a blue organic electroluminescent unit; the second organic electroluminescent unit is a green organic electroluminescent unit or a red organic electroluminescent unit.

Optionally, the organic electroluminescent device further comprises a third organic electroluminescent unit located on a side of the basal substrate departing from the first organic electroluminescent unit. The second organic electroluminescent unit and the third organic electroluminescent unit are arranged along the extension direction of the basal substrate.

Optionally, a wavelength emitted by the first organic electroluminescent unit is smaller than a wavelength emitted by the second organic electroluminescent unit and a wavelength emitted by the third organic electroluminescent unit.

Optionally, the first organic electroluminescent unit is a blue organic electroluminescent unit; the second organic electroluminescent unit is one of a green organic electroluminescent unit and a red organic electroluminescent unit; and the third organic electroluminescent unit is the other one of a green organic electroluminescent unit and a red organic electroluminescent unit.

In the organic electroluminescent device, by respectively adjusting the light emitting state of the blue organic electroluminescent unit, the green organic electroluminescent unit and the red organic electroluminescent unit, light of different colors can be emitted, realizing the function of adjustable light color.

In addition, in the organic electroluminescent device, the polarization structure and the basal substrate are arranged on a side of the blue organic electroluminescent unit departing from the light exit side. Therefore, when the blue organic electroluminescent unit emits light, most of the generated blue light can be emitted from the light exit side; only a small part of the blue light can pass through the polarization structure and the basal substrate, and enter the light emitting layer(s) of the green organic electroluminescent unit and/or the red organic electroluminescent unit. If a part of the blue light passes through the polarization structure and the basal substrate, and enters the green organic electroluminescent unit and/or the red organic electroluminescent unit, according to optical principle, after passing through the polarization structure, the blue light is converted to linearly polarized light. After passing through the basal substrate with phase retardation characteristic, the blue light is then converted to elliptically polarized light. If the green organic electroluminescent unit and/or the red organic electroluminescent unit are excited by this part of blue light with an elliptically polarized state and emit light, the emitted light of the stimulated emission will have a similar or identical polarized state as the exciting light (i.e., blue light with the elliptically polarized state). After the emitted light of the stimulated emission passes through the basal substrate with phase retardation characteristic, most of it is then converted to linearly polarized light; a relatively large angle is between a polarization direction of this linearly polarized light and a polarization direction of the polarization structure. According to optical principle, only the polarization component with a polarization direction parallel to the polarization direction of the polarization structure can pass through the polarization structure; therefore, this emitted light of the stimulated emission will be greatly extincted after passing through the polarization structure; most light of the stimulated emission cannot pass through the polarization structure. Therefore, only a small part of the blue light can pass through the polarization structure and the basal substrate, and excite the light emitting layer(s) of the green organic electroluminescent unit and/or the red organic electroluminescent unit, and there is only a little light generated by the stimulated emission; moreover, most of the emitted light of the stimulated emission cannot pass through the polarization structure or enter the blue organic electroluminescent unit, it will thus not be emitted from the light exit side of the organic electroluminescent device. Therefore, little optical noise is generated during the operation of the blue organic electroluminescent unit. On the other hand, since the photon energy of light emitted by the green organic electroluminescent unit and the red organic electroluminescent unit is relatively small, thus it cannot excite the blue organic electroluminescent unit; moreover, the green organic electroluminescent unit and the red organic electroluminescent unit are arranged along the extension direction of the basal substrate (i.e., the light exit surfaces of them are parallel to each other), therefore little optical noise is generated during the operation of the green organic electroluminescent unit and/or the red organic electroluminescent unit. In summary, little optical noise is generated during the operation of the blue organic electroluminescent unit, green organic electroluminescent unit and the red organic electroluminescent unit; the color purity of light emitted from the organic electroluminescent device is thus relatively high

Therefore, the light color of the organic electroluminescent device is adjustable; the color purity of the emitted light is relatively high.

In addition, due to the extinction effect of the polarization structure and the basal substrate, the reflectivity of the whole organic electroluminescent device for external light can be greatly reduced. The organic electroluminescent device thus has a relatively high contrast.

Optionally, the basal substrate is made of a wave plate; a 45-degree angle is between a polarization direction of the polarization structure and the optical axis of the wave plate.

Optionally, the basal substrate is made of a wave plate with a π/2 phase retardation for a wavelength of 435˜760 nm.

Optionally, the basal substrate is made of a wave plate with a phase retardation of π/2 for a certain wavelength of 435˜760 nm.

Optionally, a thickness d of the basal substrate meets:

$$d = \frac{4 m + 1}{4 \vert {n}_{o} - {n}_{e} \vert} λ ;$$

λ is a wavelength for the η/2 phase retardation of the basal substrate; nₒ and nₑ are respectively refractive indexes of ordinary light and extraordinary light generated by a light beam with a wavelength of λ incident in the basal substrate; m is a natural number.

Optionally, the second organic electroluminescent unit comprises a transparent anode layer, a hole injection layer, a hole transport layer, a light emitting layer, an electron transport layer and a reflective cathode layer sequentially arranged on the basal substrate along a direction departing from the basal substrate; the third organic electroluminescent unit comprises a transparent anode layer, a hole injection layer, a hole transport layer, a light emitting layer, an electron transport layer and a reflective cathode layer sequentially arranged on the basal substrate along a direction departing from the basal substrate.

Optionally, the reflective cathode layer of the second organic electroluminescent unit and the reflective cathode layer of the third organic electroluminescent unit form an integrated structure in the same layer.

Optionally, the first organic electroluminescent unit comprises a transparent anode layer, a hole injection layer, a hole transport layer, a light emitting layer, an electron transport layer and a transparent cathode layer sequentially arranged on the basal substrate along a direction departing from the basal substrate.

Optionally, the organic electroluminescent device further comprises: a first control circuit electrically connected with the transparent anode layer and transparent cathode layer of the first organic electroluminescent unit for controlling the light emitting state of the first organic electroluminescent unit; a second control circuit electrically connected with the transparent anode layer and reflective cathode layer of the second organic electroluminescent unit for controlling the light emitting state of the second organic electroluminescent unit; and a third control circuit electrically connected with the transparent anode layer and reflective cathode layer of the third organic electroluminescent unit for controlling the light emitting state of the third organic electroluminescent unit.

Optionally, the transparent anode layer of the second organic electroluminescent unit and the transparent anode layer of the third organic electroluminescent unit are respectively connected to the transparent anode layer of the first organic electroluminescent unit.

Optionally, the hole injection layer of the first organic electroluminescent unit, the hole injection layer of the second organic electroluminescent unit and the hole injection layer of the third organic electroluminescent unit are made of the same material; and/or the hole transport layer of the first organic electroluminescent unit, the hole transport layer of the second organic electroluminescent unit and the hole transport layer of the third organic electroluminescent unit are made of the same material; and/or the electron transport layer of the first organic electroluminescent unit, the electron transport layer of the second organic electroluminescent unit and the electron transport layer of the third organic electroluminescent unit are made of the same material.

Optionally, a thickness range for the hole injection layer of the first organic electroluminescent unit, the hole injection layer of the second organic electroluminescent unit and the hole injection layer of the third organic electroluminescent unit is 5˜40 nm; and/or a thickness range for the hole transport layer of the first organic electroluminescent unit, the hole transport layer of the second organic electroluminescent unit and the hole transport layer of the third organic electroluminescent unit is 10˜100 nm; and/or a thickness range for the light emitting layer of the first organic electroluminescent unit, the light emitting layer of the second organic electroluminescent unit and the light emitting layer of the third organic electroluminescent unit is 20˜50 nm; and/or a thickness range for the electron transport layer of the first organic electroluminescent unit, the electron transport layer of the second organic electroluminescent unit and the electron transport layer of the third organic electroluminescent unit is 10˜100 nm.

An embodiment of the invention further provides a method for manufacturing the abovementioned organic electroluminescent device. The method comprises: providing a polarization structure on a side of a basal substrate with phase retardation characteristic; forming a first organic electroluminescent unit on a side of the polarization structure departing from the basal substrate; a side of the first organic electroluminescent unit departing from the basal substrate being the light exit side of the organic electroluminescent device; and forming at least a second organic electroluminescent unit on a side of the basal substrate departing from the first organic electroluminescent unit.

Optionally, the method further comprises: forming a third organic electroluminescent unit on a side of the basal substrate departing from the first organic electroluminescent unit; the second organic electroluminescent unit and the third organic electroluminescent unit being arranged along the extension direction of the basal substrate.

An embodiment of the invention further provides a display device. The display device comprises the abovementioned organic electroluminescent device.

### BRIEF DESCRIPTION OF THE DRAWINGS

FIG. 1 is a structural schematic diagram of an organic electroluminescent device provided by an embodiment of the present invention;

FIG. 2 is a schematic diagram of an organic electroluminescent device, in which blue light enters the green organic electroluminescent unit and/or the red organic electroluminescent unit and generates light of stimulated emission; and

FIG. 3 is a flow chart of a method for manufacturing an organic electroluminescent device provided by an embodiment of the present invention.

### DETAILED DESCRIPTION OF THE INVENTION

In the following, the technical solutions in embodiments of the invention will be described clearly and completely in connection with the drawings in the embodiments of the invention. Obviously, the described embodiments are only part of the embodiments of the invention, and not all of the embodiments. Based on the embodiments in the invention, all other embodiments obtained by those of ordinary skills in the art under the premise of not paying out creative work pertain to the protection scope of the invention.

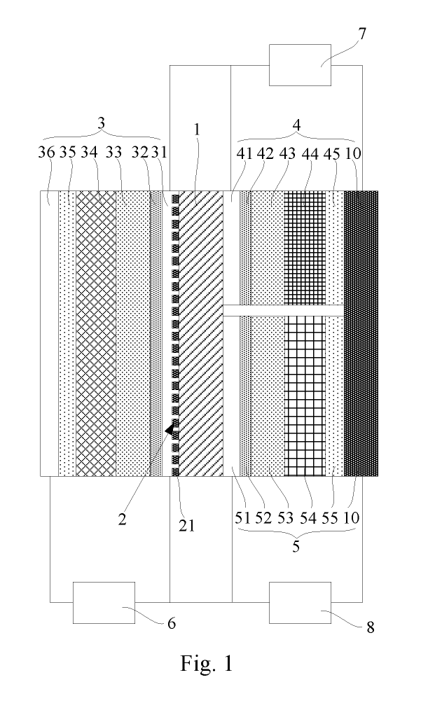

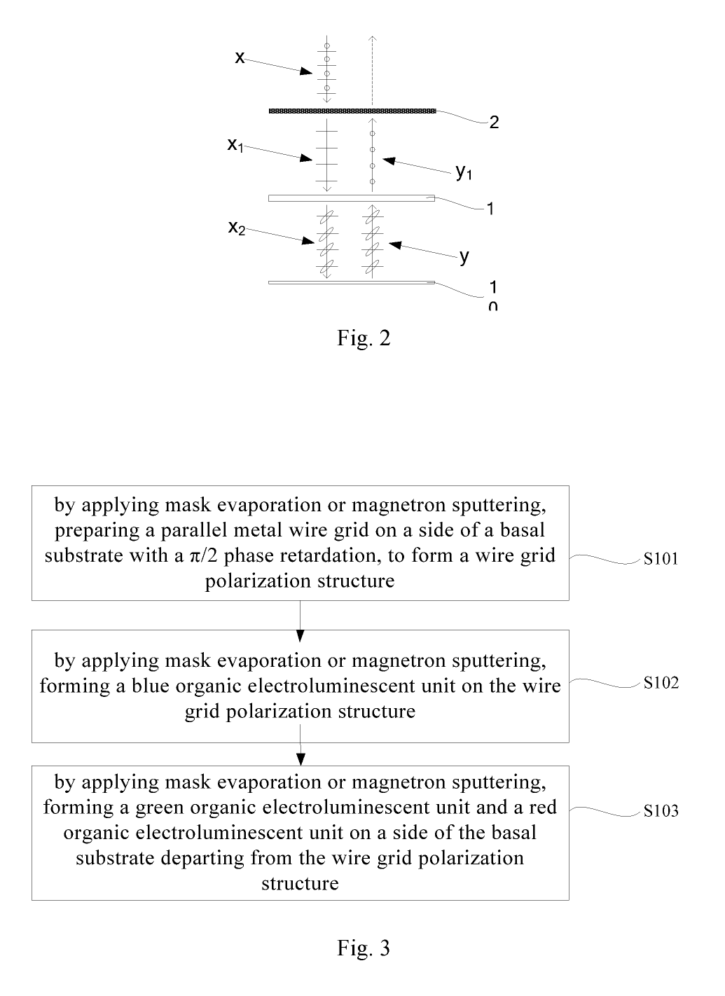

Referring to FIG. 1 and FIG. 2, an embodiment of the present invention provides an organic electroluminescent device. As can be seen from FIG. 1, the organic electroluminescent device comprises: a basal substrate 1 with phase retardation characteristic; a polarization structure 2 (e.g., a wire grid polarization structure) provided on a side of the basal substrate 1.

A blue organic electroluminescent unit 3 is located on a side of the polarization structure 2 departing from the basal substrate 1; a side of the blue organic electroluminescent unit 3 departing from the basal substrate 1 is the light exit side of the organic electroluminescent device.

A green organic electroluminescent unit 4 and a red organic electroluminescent unit 5 are located on a side of the basal substrate 1 departing from the blue organic electroluminescent unit 3. The green organic electroluminescent unit 4 and the red organic electroluminescent unit 5 are arranged along the extension direction of the basal substrate 1. The light exit surface area of the green organic electroluminescent unit 4 can be same or different with that of the red organic electroluminescent unit 5; their ratios can be selected based on the white balance of the device.

In the organic electroluminescent device, by respectively adjusting the light emitting state of the blue organic electroluminescent unit 3, the green organic electroluminescent unit 4 and the red organic electroluminescent unit 4, light of different colors can be emitted, realizing the function of adjustable light color.

In addition, in the organic electroluminescent device, the polarization structure 2 and the basal substrate 1 are arranged on a side of the blue organic electroluminescent unit 3 departing from the light exit side. Therefore, when the blue organic electroluminescent unit 3 emits light, most of the generated blue light can be emitted from the light exit side; only a small part of the blue light can pass through the polarization structure 2 and the basal substrate 1, and enter the light emitting layer(s) of the green organic electroluminescent unit 4 and/or the red organic electroluminescent unit 5. If a part of the blue light passes through the polarization structure 2 and the basal substrate 1, and enters the green organic electroluminescent unit and/or the red organic electroluminescent unit, according to optical principle, as shown in FIG. 2, after passing through the polarization structure 2, the blue light x is converted to linearly polarized light x₁. After passing through the basal substrate with phase retardation characteristic, the blue linearly polarized light x₁ is then converted to elliptically polarized light x₂. If the green organic electroluminescent unit 4 and/or the red organic electroluminescent unit 5 are excited by this part of blue light with an elliptically polarized state and emit light (indicated with “y” in FIG. 2), the emitted light y of the stimulated emission will have a similar or identical polarized state as the exciting light (i.e., the blue elliptically polarized light x₂); that is, the emitted light y of the stimulated emission is elliptically polarized light too. After the emitted light y of the stimulated emission passes through the basal substrate 1 with phase retardation characteristic, most of the emitted light y is then converted to linearly polarized light; a relatively large angle is between a polarization direction of this linearly polarized light and a polarization direction of the polarization structure (e.g., a direction perpendicular to the extension direction of the wire in the wire grid polarization structure). According to optical principle, only the polarization component with a polarization direction parallel to the polarization direction of the polarization structure can pass through the polarization structure; therefore, this emitted light of the stimulated emission will be greatly extincted after passing through the polarization structure 2 (as shown in FIG. 2, the polarization component y₁ of the linearly polarized light y is perpendicular to the polarization direction of the polarization structure 2, thus the polarization component y₁ cannot pass through the polarization structure 2); most light y of the stimulated emission cannot pass through the polarization structure 2. Therefore, only a small part of the blue light x can pass through the polarization structure 2 and the basal substrate 1, and excite the light emitting layer(s) of the green organic electroluminescent unit 4 and/or the red organic electroluminescent unit 5, and there is only a little light y generated by the stimulated emission; moreover, most of the emitted light y of the stimulated emission cannot pass through the polarization structure 2 or enter the blue organic electroluminescent unit 3, it will thus not be emitted from the light exit side of the organic electroluminescent device to generate optical noise. Therefore, little optical noise is generated during the operation of the blue organic electroluminescent unit 3. On the other hand, since the photon energy of light emitted by the green organic electroluminescent unit 4 and the red organic electroluminescent unit 5 is relatively small, thus it cannot excite the blue organic electroluminescent unit 3; moreover, the green organic electroluminescent unit 4 and the red organic electroluminescent unit 5 are arranged along the extension direction of the basal substrate 1 (i.e., the light exit surfaces of them are parallel to each other), therefore little optical noise is generated during the operation of the green organic electroluminescent unit 4 and/or the red organic electroluminescent unit 5. In summary, little optical noise is generated during the operation of the blue organic electroluminescent unit 3, green organic electroluminescent unit 4 and the red organic electroluminescent unit 5; the color purity of light emitted from the organic electroluminescent device is thus relatively high.

Therefore, the light color of the organic electroluminescent device is adjustable; the color purity of the emitted light is relatively high. In addition, due to the extinction effect of the polarization structure 2 and the basal substrate 1, the reflectivity of the whole organic electroluminescent device for external light can be greatly reduced. The organic electroluminescent device thus has a relatively high contrast.

In an embodiment of the present invention, only green organic electroluminescent unit or only red organic electroluminescent unit is arranged on the side of the basal substrate 1 departing from the blue organic electroluminescent unit 3. In this manner, light beams of two colors can be combined to produce other colors. Moreover, the organic electroluminescent device in this embodiment also has the advantages as the embodiment shown in FIG. 1.

In an embodiment of the present invention, the basal substrate 1 is made of a wave plate; a 45-degree angle is between a polarization direction of the polarization structure 2 and the optical axis of the wave plate. As shown in FIG. 2, a 45-degree angle is between the polarization direction of the polarization structure 2 and the optical axis of the wave plate, light passing through the polarization structure 2 and the basal substrate 1 is then converted to elliptically polarized light. Optionally, processes such as mask evaporation and magnetron sputtering can be applied to form thin parallel metal wires on a side of the basal substrate 1, forming a wire grid polarization structure 2.

Optionally, the wave plate is made of a polymer material. The basal substrate 1 can be made of a polymer material with a refractive index close to the refractive index of the organic electroluminescent units, thereby reducing the total reflection at the interface of the basal substrate. Therefore, the organic electroluminescent device in the embodiment of the invention can also be applied as a flexible organic electroluminescent device. Certainly, the wave plate can also be a crystal wave plate, which is formed by slicing a uniaxial crystal along a direction parallel to the optical axis.

On the basis of the above embodiments, in an embodiment of the present invention, the basal substrate 1 is made of a wave plate with a π/2 phase retardation for a wavelength of 435˜760 nm. Optionally, the basal substrate 1 is made of a wave plate with a phase retardation of π/2 for a certain wavelength of 435˜760 nm. In an embodiment, the wave plate is a wave plate with a phase retardation of π/2 for blue light with a wavelength of 450 nm. Alternatively, considering the light colors of the three organic electroluminescent units in the organic electroluminescent device provided by the embodiment of the invention, the wave plate can be a wave plate with a phase retardation of π/2 for light with a wavelength of 550 nm.

On the basis of the above embodiments, in an embodiment of the present invention, a thickness d of the basal substrate 1 meets:

$$d = \frac{4 m + 1}{4 \vert {n}_{o} - {n}_{e} \vert} λ ;$$

λ is a wavelength for the π/2 phase retardation of the basal substrate 1; λ can be selected as 450 nm or 550 nm according to the abovementioned embodiments. nₒ and nₑ are respectively refractive indexes of ordinary light (o light) and extraordinary light (e light) generated by a light beam with a wavelength of λ incident in the basal substrate 1; if λ is selected as 550 nm, nₒ and nₑ are respectively refractive indexes of o light and e light generated by a light beam with a wavelength of 550 nm incident in the basal substrate 1. m is a natural number such as 0, 1, 2 and 3.

As shown in FIG. 1, in an embodiment of the present invention, the green organic electroluminescent unit 4 comprises a transparent anode layer 41, a hole injection layer 42, a hole transport layer 43, a light emitting layer 44, an electron transport layer 45 and a reflective cathode layer 10 sequentially arranged on the basal substrate along a direction departing from the basal substrate 1; the red organic electroluminescent unit 5 comprises a transparent anode layer 51, a hole injection layer 52, a hole transport layer 53, a light emitting layer 54, an electron transport layer 55 and a reflective cathode layer 10 sequentially arranged on the basal substrate along a direction departing from the basal substrate 1.

Optionally, the transparent anode layer 41 of the green organic electroluminescent unit 4 and the transparent anode layer 51 of the red organic electroluminescent unit 5 can be made of indium tin oxide (ITO) material; they can also be formed simultaneously. In particular, the manufacturing process comprises: firstly, applying a process such as magnetron sputtering to form an indium tin oxide (ITO) film with a thickness of 100 nm on a side of the basal substrate 1 departing from the wire grid polarization structure 2; then forming two separate ITO layers by etching method. These two separate ITO layers are respectively used as the transparent anode layer 41 and transparent anode layer 51.

As shown in FIG. 1, on the basis of the above embodiments, in an optional embodiment, the reflective cathode layer of the green organic electroluminescent unit 4 and the reflective cathode layer of the red organic electroluminescent unit 5 form an integrated structure in the same layer; i.e., the green organic electroluminescent unit 4 and the red organic electroluminescent unit 5 share a single reflective cathode layer 10. Light generated within the organic electroluminescent device can be reflected on the surface of the reflective cathode layer 10 and transmitted towards the light exit side; ensuring a high output efficiency for the organic electroluminescent device. Optionally, a composite structure such as Mg:Ag(9:1, 1˜5 nm)/Ag(100˜200 nm), LiF(1 nm)/Al(100˜200 nm) or Yb(1 nm)/Ag(100˜200 nm) can be applied in the reflective cathode layer 10, which can be formed with evaporation.

As shown in FIG. 1, on the basis of the above embodiments, in an embodiment, the blue organic electroluminescent unit 3 comprises a transparent anode layer 31, a hole injection layer 32, a hole transport layer 33, a light emitting layer 34, an electron transport layer 35 and a transparent cathode layer 36 sequentially arranged on the basal substrate 1 along a direction departing from the basal substrate 1. Optionally, the transparent anode layer 31 in the blue organic electroluminescent unit 3 can be made of indium tin oxide (ITO) material. The transparent cathode layer 36 can be transparent or translucent. For a transparent cathode layer with a transparent state, a composite structure such as LiF(0.5 nm)/Al(1˜3 nm)/ITO(30˜50 nm) or Li(1 nm)/ITO(30˜50 nm) can be applied; the transmittance is 80%˜90%. For a transparent cathode layer 36 with a translucent state, it can be realized by evaporate plating a film of Mg:Ag or LiF(1 nm)/Al, with an overall thickness of 10˜15 nm; the transmittance should be greater than 60%.

On the basis of the above embodiments, in an embodiment, the functions of the hole injection layer 32 of the blue organic electroluminescent unit 3, the hole injection layer 42 of the green organic electroluminescent unit 4 and the hole injection layer 52 of the red organic electroluminescent unit 5 are same, i.e., improving the hole injection efficiency and eliminating defects for the transparent anode layer. These layers can be made of either the same material or different materials. Materials such as HAT-CN and a-NPD:F4-TCNQ can be selected. A thickness range of these layers can be 5˜40 nm.

The functions of the hole transport layer 33 of the blue organic electroluminescent unit 3, the hole transport layer 43 of the green organic electroluminescent unit 4 and the hole transport layer 53 of the red organic electroluminescent unit 5 are same, i.e., improving the hole transport into the light emitting layer. These layers can be made of either the same material or different materials. Materials such as NPB and Spiro-TAD can be selected. A thickness range of these layers can be 10˜100 nm.

The thickness range of the blue light emitting layer 34, green light emitting layer 44 and red light emitting layer 54 can be 20˜50 nm. The blue light emitting layer 34 can be made of short wave organic light emitting system in organic luminescent materials (e.g., blue light system CBP:FIrpic). The green light emitting layer 44 and red light emitting layer 54 can be made of long wave organic light emitting system in organic luminescent materials (e.g., green light system CBP:Ir(ppy)3 for green light emitting layer 44, red light system CBP:Q3IR or yellow light system CPB:(bt)Ir(acac) for red light emitting layer 54).

The functions of the electron transport layer 35 of the blue organic electroluminescent unit 3, the electron transport layer 45 of the green organic electroluminescent unit 4 and the electron transport layer 55 of the red organic electroluminescent unit 5 are same, i.e., reducing the interface barrier during electron transport. These layers can be made of either the same material or different materials. N-doping structures such as Alq3:Li and BPhen:Cs with a conductivity of about 10⁻⁵ S/cm can be selected. A thickness range of these layers can be 10˜100 nm.

Optionally, the layers in the abovementioned organic electroluminescent units can be prepared by means of vacuum coating.

As shown in FIG. 1, on the basis of the above embodiments, in an embodiment, the organic electroluminescent device further comprises: a first control circuit 6 electrically connected with the transparent anode layer 31 and transparent cathode layer 36 of the blue organic electroluminescent unit 3 for controlling the light emitting state of the blue organic electroluminescent unit 3; a second control circuit 7 electrically connected with the transparent anode layer 41 and reflective cathode layer of the green organic electroluminescent unit 4 for controlling the light emitting state of the green organic electroluminescent unit 4; and a third control circuit 8 electrically connected with the transparent anode layer 51 and reflective cathode layer of the red organic electroluminescent unit 5 for controlling the light emitting state of the red organic electroluminescent unit 5. With these control circuit, the blue organic electroluminescent unit 3, green organic electroluminescent unit 4 and red organic electroluminescent unit 5 can be driven and emit light. The light emitting states of these organic electroluminescent units can be controlled respectively, realizing emitted light of different colors. For example, if the blue organic electroluminescent unit 3, green organic electroluminescent unit 4 and red organic electroluminescent unit 5 are all driven and emit light, the organic electroluminescent device emits white light.

As shown in FIG. 1, optionally, the transparent anode layer 41 of the green organic electroluminescent unit 4 and the transparent anode layer 51 of the red organic electroluminescent unit 5 are respectively connected to the transparent anode layer 31 of the blue organic electroluminescent unit 3. In this manner, both sides of the basal substrate 1 can have the same potential; when the organic electroluminescent units on both side of the basal substrate 1 are driven simultaneously, no capacitance effect will be formed between the basal substrate 1 and the transparent electrodes on both sides; therefore, the driving voltage will not be affected.

An embodiment of the invention further provides a method for manufacturing the abovementioned organic electroluminescent device. As shown in FIG. 1, the method comprises forming a blue organic electroluminescent unit 3, a green organic electroluminescent unit 4 and a red organic electroluminescent unit 5 on both sides of a basal substrate 1. The green organic electroluminescent unit 4 and the red organic electroluminescent unit 5 are arranged on a side of the basal substrate 1 departing from the blue organic electroluminescent unit 3; the green organic electroluminescent unit 4 and the red organic electroluminescent unit 5 are arranged along the extension direction of the basal substrate 1. A side of the blue organic electroluminescent unit 3 departing from the basal substrate 1 is the light exit side of the organic electroluminescent device. The basal substrate 1 is a basal substrate with phase retardation characteristic; a polarization structure 2 is provided on a side of a basal substrate facing the blue organic electroluminescent unit 3.

The light color of the organic electroluminescent device manufactured with the abovementioned method is adjustable; the color purity of the emitted light is relatively high. In addition, the contrast of the organic electroluminescent device is also high.

As shown in FIG. 1 and FIG. 3, in an embodiment, the method for manufacturing the organic electroluminescent device may comprise the following steps.

Step S101: by applying mask evaporation or magnetron sputtering, preparing a parallel metal wire grid on a side of a basal substrate 1 with a η/2 phase retardation, to form a wire grid polarization structure 2.

Step S102: by applying mask evaporation or magnetron sputtering, forming a blue organic electroluminescent unit 3 on the wire grid polarization structure 2.

Step S103: by applying mask evaporation or magnetron sputtering, forming a green organic electroluminescent unit 4 and a red organic electroluminescent unit 5 on a side of the basal substrate 1 departing from the wire grid polarization structure 2.

Certainly, the abovementioned embodiment is only an example of the method for manufacturing the organic electroluminescent device. The method for manufacturing the organic electroluminescent device of the invention is not limited to the content of the abovementioned embodiment.

In an embodiment, only green organic electroluminescent unit or only red organic electroluminescent unit is arranged on the side of the basal substrate 1 departing from the blue organic electroluminescent unit 3. In this manner, light beams of two colors can be combined to produce other colors. Moreover, the organic electroluminescent device in this embodiment also has the advantages as the embodiment shown in FIG. 1.

An embodiment of the invention further provides a display device. The display device comprises the abovementioned organic electroluminescent device. The light color of the display device is adjustable; the color purity of the emitted light is relatively high.

Apparently, the person skilled in the art may make various alterations and variations to the invention without departing the spirit and scope of the invention. As such, provided that these modifications and variations of the invention pertain to the scope of the claims of the invention and their equivalents, the invention is intended to embrace these alterations and variations.

1. An organic electroluminescent device comprising:
a basal substrate with phase retardation characteristic; a polarization structure provided on a side of the basal substrate;
a first organic electroluminescent unit located on a side of the polarization structure departing from the basal substrate; a side of the first organic electroluminescent unit departing from the basal substrate being the light exit side of the organic electroluminescent device; and
at least a second organic electroluminescent unit located on a side of the basal substrate departing from the first organic electroluminescent unit.

2. The organic electroluminescent device according to claim 1, wherein a wavelength emitted by the first organic electroluminescent unit is smaller than a wavelength emitted by the second organic electroluminescent unit.

3. The organic electroluminescent device according to claim 2, wherein the first organic electroluminescent unit is a blue organic electroluminescent unit; and wherein the second organic electroluminescent unit is a green organic electroluminescent unit or a red organic electroluminescent unit.

4. The organic electroluminescent device according to claim 1, further comprising:
a third organic electroluminescent unit located on a side of the basal substrate departing from the first organic electroluminescent unit;
wherein the second organic electroluminescent unit and the third organic electroluminescent unit are arranged along the extension direction of the basal substrate.

5. The organic electroluminescent device according to claim 4, wherein a wavelength emitted by the first organic electroluminescent unit is smaller than a wavelength emitted by the second organic electroluminescent unit and a wavelength emitted by the third organic electroluminescent unit.

6. The organic electroluminescent device according to claim 5, wherein the first organic electroluminescent unit is a blue organic electroluminescent unit; wherein the second organic electroluminescent unit is one of a green organic electroluminescent unit and a red organic electroluminescent unit; and wherein the third organic electroluminescent unit is the other one of a green organic electroluminescent unit and a red organic electroluminescent unit.

7. The organic electroluminescent device according to claim 1, wherein the basal substrate is made of a wave plate; wherein a 45-degree angle is between a polarization direction of the polarization structure and the optical axis of the wave plate.

8. The organic electroluminescent device according to claim 7, wherein the basal substrate is made of a wave plate with a π/2 phase retardation for a wavelength of 435˜760 nm.

9. The organic electroluminescent device according to claim 8, wherein the basal substrate is made of a wave plate with a phase retardation of π/2 for a certain wavelength of 435˜760 nm.

10. The organic electroluminescent device according to claim 9, wherein a thickness d of the basal substrate meets:
$$d = \frac{4 m + 1}{4 \vert {n}_{o} - {n}_{e} \vert} λ ;$$
wherein λ is a wavelength for the π/2 phase retardation of the basal substrate; nₒ and nₑ are respectively refractive indexes of ordinary light and extraordinary light generated by a light beam with a wavelength of λ incident in the basal substrate; m is a natural number.

11. The organic electroluminescent device according to claim 6, wherein the second organic electroluminescent unit comprises a transparent anode layer, a hole injection layer, a hole transport layer, a light emitting layer, an electron transport layer and a reflective cathode layer sequentially arranged on the basal substrate along a direction departing from the basal substrate;
and wherein the third organic electroluminescent unit comprises a transparent anode layer, a hole injection layer, a hole transport layer, a light emitting layer, an electron transport layer and a reflective cathode layer sequentially arranged on the basal substrate along a direction departing from the basal substrate.

12. The organic electroluminescent device according to claim 11, wherein the reflective cathode layer of the second organic electroluminescent unit and the reflective cathode layer of the third organic electroluminescent unit form an integrated structure in the same layer.

13. The organic electroluminescent device according to claim 11, wherein the first organic electroluminescent unit comprises a transparent anode layer, a hole injection layer, a hole transport layer, a light emitting layer, an electron transport layer and a transparent cathode layer sequentially arranged on the basal substrate along a direction departing from the basal substrate.

14. The organic electroluminescent device according to claim 13, further comprising:
a first control circuit electrically connected with the transparent anode layer and transparent cathode layer of the first organic electroluminescent unit for controlling the light emitting state of the first organic electroluminescent unit;
a second control circuit electrically connected with the transparent anode layer and reflective cathode layer of the second organic electroluminescent unit for controlling the light emitting state of the second organic electroluminescent unit; and
a third control circuit electrically connected with the transparent anode layer and reflective cathode layer of the third organic electroluminescent unit for controlling the light emitting state of the third organic electroluminescent unit.

15. The organic electroluminescent device according to claim 14, wherein the transparent anode layer of the second organic electroluminescent unit and the transparent anode layer of the third organic electroluminescent unit are respectively connected to the transparent anode layer of the first organic electroluminescent unit.

16. The organic electroluminescent device according to claim 13, wherein the hole injection layer of the first organic electroluminescent unit, the hole injection layer of the second organic electroluminescent unit and the hole injection layer of the third organic electroluminescent unit are made of the same material; and/or
the hole transport layer of the first organic electroluminescent unit, the hole transport layer of the second organic electroluminescent unit and the hole transport layer of the third organic electroluminescent unit are made of the same material; and/or
the electron transport layer of the first organic electroluminescent unit, the electron transport layer of the second organic electroluminescent unit and the electron transport layer of the third organic electroluminescent unit are made of the same material.

17. The organic electroluminescent device according to claim 13, wherein a thickness range for the hole injection layer of the first organic electroluminescent unit, the hole injection layer of the second organic electroluminescent unit and the hole injection layer of the third organic electroluminescent unit is 5˜40 nm; and/or
a thickness range for the hole transport layer of the first organic electroluminescent unit, the hole transport layer of the second organic electroluminescent unit and the hole transport layer of the third organic electroluminescent unit is 10˜100 nm; and/or
a thickness range for the light emitting layer of the first organic electroluminescent unit, the light emitting layer of the second organic electroluminescent unit and the light emitting layer of the third organic electroluminescent unit is 20˜50 nm; and/or
a thickness range for the electron transport layer of the first organic electroluminescent unit, the electron transport layer of the second organic electroluminescent unit and the electron transport layer of the third organic electroluminescent unit is 10˜100 nm.

18. A method for manufacturing an organic electroluminescent device, comprising:
providing a polarization structure on a side of a basal substrate with phase retardation characteristic;
forming a first organic electroluminescent unit on a side of the polarization structure departing from the basal substrate; a side of the first organic electroluminescent unit departing from the basal substrate being the light exit side of the organic electroluminescent device; and
forming at least a second organic electroluminescent unit on a side of the basal substrate departing from the first organic electroluminescent unit.

19. The method according to claim 18, further comprising:
forming a third organic electroluminescent unit on a side of the basal substrate departing from the first organic electroluminescent unit; the second organic electroluminescent unit and the third organic electroluminescent unit being arranged along the extension direction of the basal substrate.

20. A display device comprising the organic electroluminescent device according to claim 1.
